(19) United States
(12) Patent Application Publication
(10) Pub. No.: US 2020/0196490 A1
(43) Pub. Date: Jun. 18, 2020

(54) DEVICE FOR COOLING AVIONICS RACKS WITH A HEAT-TRANSFER FLUID

(71) Applicants: SAFRAN ELECTRONICS & DEFENSE, BOULOGNE BILLANCOURT (FR); SAFRAN ELECTRICAL & POWER, BLANGAC CEDEX (FR)

(72) Inventors: François GUILLOT, BOULOGNE BILLANCOURT (FR); Jean-Marc BLINEAU, BLAGNAC CEDEX (FR); Philippe AVIGNON, BLAGNAC CEDEX (FR); Serge ROQUES, BLAGNAC CEDEX (FR); Franck ALBERO, BLAGNAC CEDEX (FR)

(21) Appl. No.: 16/621,654

(22) PCT Filed: Jun. 1, 2018
(86) PCT No.: PCT/EP2018/064528

§ 371 Date: Feb. 24, 2020

(30) Foreign Application Priority Data
Jun. 12, 2017 (FR) 17 55242

(51) Int. Cl. H05K 7/20; B64D 13/06

(52) U.S. Cl. CPC H05K 7/20872; H05K 7/20863; B64D 2013/0614; H05K 7/20272; B64D 13/06; H05K 7/20172

(57) ABSTRACT

A device for cooling an electronic module placed in an avionics rack of an aircraft comprising a ventilated cabin, the cooling device comprising: a closed circuit for circulating a heat-transfer fluid; first means for circulating the heat-transfer fluid in the closed circuit; a first heat exchanger comprising a cold circuit which is provided with first means for connecting to the closed circuit for circulating a heat-transfer fluid and which is thermally connected to a hot source of the avionics rack; a second heat exchanger comprising a hot circuit provided with second means for connecting to the closed circuit for circulating a heat-transfer fluid and a cold circuit thermally connected to an air exhaust from the ventilated cabin. An avionics rack and an aircraft comprising such a rack.

### FIELD OF THE INVENTION

The invention applies to the field of avionics racks intended to receive electronic modules and more particularly to the devices for cooling such racks.

### BACKGROUND OF THE INVENTION

In an aircraft, the management of flight controls and all the information necessary for the proper functioning of the aircraft is carried out by electronic modules plugged into one or more avionics rack(s) distributed throughout the aircraft. In operation, the electronic modules generate heat that must be removed in order not to compromise the integrity of the modules and/or their performance. This removal is typically done using a device for cooling an electronic module placed in an aircraft rack that includes means to force a flow of ventilation air into the avionics rack. This air flow is extracted and returned to a ventilation circuit that runs through the aircraft. The miniaturization of the components and therefore their concentration in the electronic modules increases the amount of heat to be evacuated. It is then necessary to also increase the volume of ventilation air passing through the rack. It has been considered to increase the air flow rates in the ventilation circuit, but such a solution is noisy and requires increasing the diameter of the ventilation ducts as well. The routing of the ventilation ducts then increases in complexity, and therefore in cost and the weight of the ducts increases accordingly.

### PURPOSE OF THE INVENTION

The purpose of the invention is to reduce the size of a device for cooling an electronic module placed in an aircraft rack.

### SUMMARY OF THE INVENTION

For this purpose, a device is provided for cooling at least one electronic module placed in an avionics rack of an aircraft including a ventilated cabin. The cooling device comprises a closed circuit for circulating a heat-transfer fluid, first means for circulating the heat-transfer fluid in the closed circuit, and a first heat exchanger comprising a cold circuit which is provided with first means for connecting to the closed circuit for circulating the heat-transfer fluid and which is thermally connected to a hot source in the aircraft rack. According to the invention, the device comprises a second heat exchanger comprising a hot circuit provided with second means for connecting the closed circuit for circulating a heat-transfer fluid and a cold circuit thermally connected to an air exhaust of the ventilated cabin.

A previously lost resource is then exploited as a cold source, namely the air flow at the outlet of the air exhaust of the ventilated cabin.

The reliability of the cooling device is improved when the first heat exchanger includes first means for forcing an air flow and/or the second heat exchanger includes second means for forcing an air flow.

A particularly robust and economical device is obtained when the first and/or second means for forcing an air flow include a fan.

The reliability of the cooling device is further improved when the first heat exchanger includes second means for circulating the heat-transfer fluid in the closed circuit.

Advantageously, the cooling device comprises means for controlling and supplying the first means for forcing an air flow, which allows the latter to be activated only when necessary, thus reducing the power consumption of the cooling device.

Advantageously, the first means for circulating the heat-transfer fluid comprise a turbine whose rotor acts as a short-circuited armature. This design is advantageous due to its simplicity of construction, use and maintenance, as well as its robustness and low manufacturing cost. In case of turbine failure, the fluid flow is not blocked, further improving the reliability of the cooling device.

The invention also relates to a method for cooling an electronic module of an aircraft rack comprising a first step of transferring heat from the electronic module to a closed circuit for circulating a heat-transfer fluid and a second step of removing the heat from the heat-transfer fluid to an air flow extracted from an air exhaust in an aircraft cabin.

The invention also relates to an avionics rack comprising a first heat exchanger whose cold circuit is provided with first means for connecting a closed circuit for circulating a heat-transfer fluid, as well as such an avionics rack in which the first heat exchanger is arranged to exchange a heat by conduction with the heat-transfer fluid.

Finally, the invention also includes an aircraft with a previously described cooling device and/or an avionics rack of a type described above.

Other characteristics and advantages of the invention will become apparent from the following description of a non-restrictive embodiment of the invention.

### BRIEF DESCRIPTION OF THE DRAWINGS

Reference will now be made to the appended drawings, wherein:

FIG. 1 is a schematic plane view of an aircraft comprising a cooling device according to the invention;

FIG. 2 is a schematic view, in perspective, of a first avionics rack according to the invention;

FIG. 3 is a schematic view, in perspective, of a second avionics rack according to the invention;

FIG. 4 is a schematic sectional view along the plane V-V of the turbine of the device of FIG. 1;

FIG. 5 is a schematic sectional view along the plane V-V of the turbine of FIG. 4;

### DETAILED DESCRIPTION OF THE INVENTION

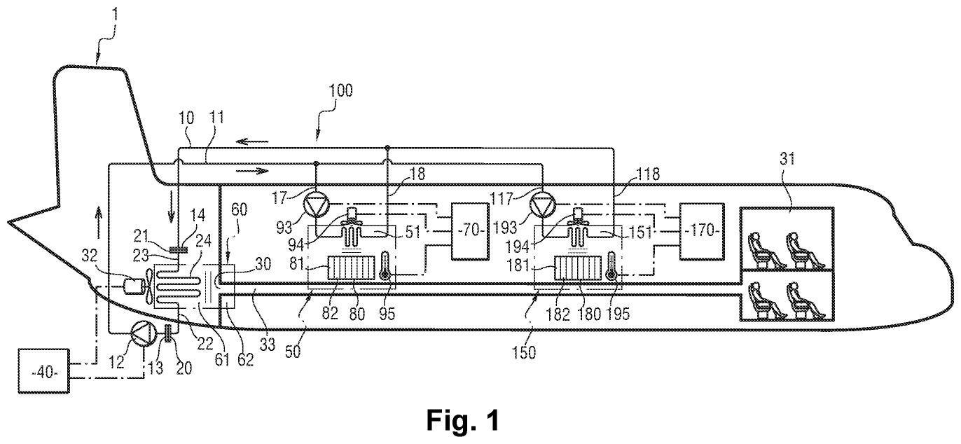

With reference to FIG. 1, the cooling device of the invention, generally referred to as 100, is intended to cool a first avionics rack 80 of an aircraft 1 which two electronic modules 81 and 82 and a second avionics rack 180, identical to the first avionics rack 80—are plugged in, which two electronic modules 181 and 182 are plugged in.

The cooling device 100 consists of a closed circuit 10 for circulating glycol water 11 made of aluminium tube and a circulation pump 12. The closed circuit 10 includes a first flat flange 13 and a second flat flange 14 respectively connected to homologous flanges 20 and 21 of an inlet 22 and an outlet 23 of a first aluminium coil 24. The first coil 24 is placed opposite an air exhaust 30 of an air-conditioned cabin 31 designed to accommodate passengers. A first fan 32 connected to a control unit 40 is arranged to force an air flow on the first coil 24.

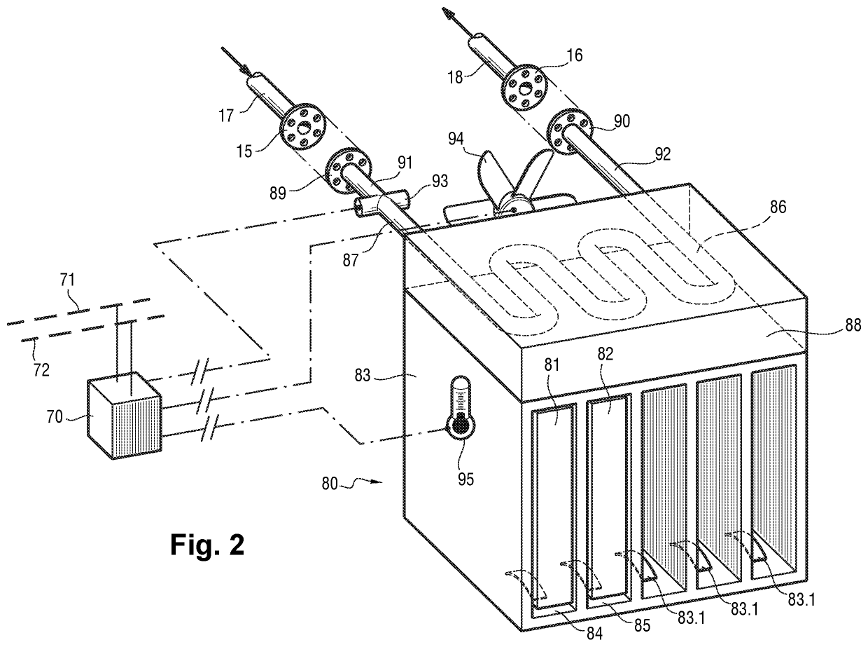

With reference to FIG. 2, the first avionics rack 80 includes a first aluminium parallelepiped frame 83 defining first cells 84 and 85 for receiving the first electronic modules 81 and 82. The first avionics rack 80 includes a first power and communication unit 70 that connects the first electronic modules 81 and 82 to the aircraft 1 power and communication/control networks 71 and 72. The first electronic modules 81 and 82 are held in place in the first cells 84 and 85 using first bronze spring blades 83.1 attached to the first frame 83. A second coil 86 made from a bent aluminum tube 87 is welded to a first plate 88 for closing the upper part of the first frame 83. The first plate 88 is also welded to the first frame 83. The second coil 86 includes a third and a fourth flat flange 89 and 90 respectively placed on a first inlet line 91 and a first outlet line 92 of the second coil 86. The third and fourth flat flanges 89 and 90 are connected to first and second homologous flanges 15 and 16 respectively for connection to the closed circuit 10. The first flange 15 is integral with a first outlet 17 of the glycol water 11 inlet tap 17 of the closed circuit 10 and the second flange 16 is integral with a second glycol water 11 return tap 18 to the closed circuit 10. The first inlet line 91 comprises a first wet rotor circulator 93 connected to the first power supply and communication unit 70. A second fan 94 also connected to the first power and communication unit 70 is arranged to force an air flow on the second coil 86. The first avionics rack 80 also comprises a first resistive internal temperature sensor 95 connected to the first power and communication unit 70.

The second coil 86, with the first frame 83 of the first avionics rack 80, produces a first heat exchanger 50 whose cold circuit 51, consisting of the second coil 86, is connected to the closed circuit 10. The second coil 86 is thermally connected to the first frame 83 which is a hot source 52 of the first heat exchanger 50, and exchanges heat, mainly by conduction, with the first electronic modules 81 and 82. Thus the glycol water 11 entering at an inlet temperature T₉₁ in the first inlet pipe 91 of the second coil 86 cools the first frame 83 by conduction, and exits the second coil 86 through the first outlet pipe 92 at an outlet temperature 92 higher than the inlet temperature T₉₁.

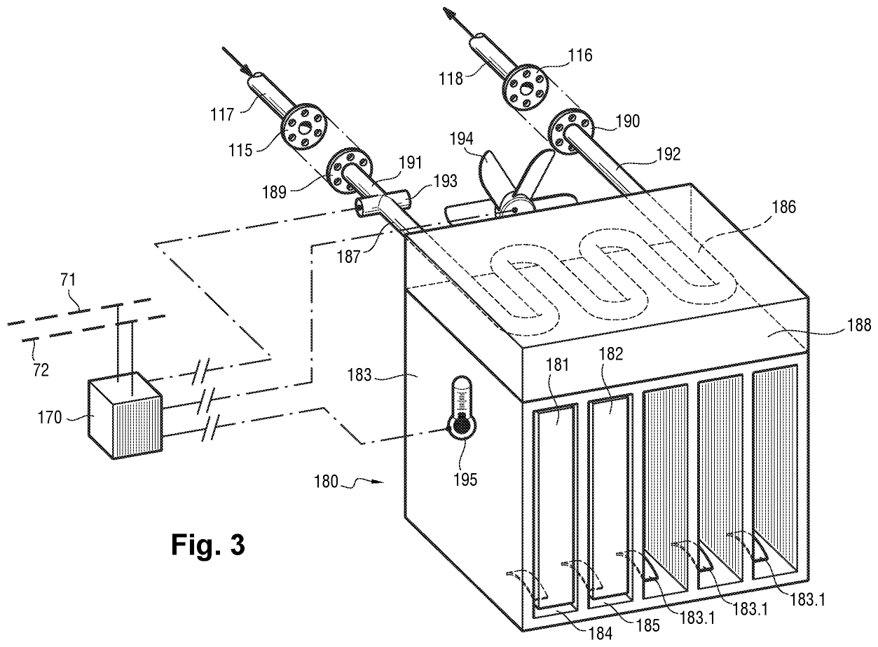

Similarly, and with reference to FIG. 3, the second avionics rack 180 comprises a second aluminium parallelepiped frame 183 defining second cells 184 and 185 for receiving the second electronic modules 181 and 182. The second avionics rack 180 comprises a second power and communication unit 170 that connects the second electronic modules 181 and 182 to the aircraft 1 power and communication/control networks 71 and 72. The second electronic modules 181 and 182 are held in place in the second cells 184 and 185 using second bronze spring blades 183.1 integral with the second frame 183. A third coil 186 made from a bent aluminum tube 187 is welded to a second plate 188 for closing the upper part of the second frame 183. The second plate 188 is also welded to the second frame 183. The third coil 186 comprises a fifth and a sixth flat flange 189 and 190 respectively placed on a second inlet pipe 191 and a second outlet pipe 92 of the third coil 186. The fifth and sixth flat flanges 189 and 190 are respectively connected to third and fourth homologous flanges 115 and 116 for connection to the closed circuit 10. The third flange 115 is integral with a third glycol water 11 inlet tap 117 of the closed circuit 10 and the fourth flange 116 is integral with a fourth outlet glycol water 11 return tap 118 to the closed circuit 10. The second inlet line 191 includes a second wet rotor circulator 193 connected to the second power supply and communication unit 170. A third fan 194 also connected to the second power and communication unit 170 is arranged to force an air flow on the third coil 186. The second avionics rack 180 also comprises a second resistive internal temperature sensor 195 connected to the second power and communication unit 170.

The third coil 186, with the second frame 183 of the second avionics rack 180, produces a second heat exchanger 150 whose cold circuit 151, consisting of the third coil 186, is connected to the closed circuit 10. The third coil 186 is thermally connected to the second frame 183, which is a hot source 152 of the second heat exchanger 150, and exchanges heat, mainly by conduction, with the second electronic modules 181 and 182. Thus the glycol water 11 entering at an inlet temperature T₁₉₁ in the second inlet pipe 191 of the third coil 186 cools the second frame 183 by conduction, and exits the third coil 186 through the second outlet pipe 192 at an outlet temperature T₁₉₂ higher than the inlet temperature T₁₉₁.

The first coil 24 produces, with the air exhaust 30 of the cabin 31, a third heat exchanger 60 whose hot circuit 61, consisting of the first coil 24, is connected to the closed circuit 10. The first coil 24 is thermally connected to the air exhaust 30, which is a cold source 62 of the third heat exchanger 60, and exchanges heat by conduction with the air exhaust 30. Thus, the glycol water 11 entering at an inlet temperature T₂₂ in the first coil 24 cools by convective exchange with an air flow 33 from the air exhaust 30 and exits the first coil 24 at an outlet temperature T₂₃ lower than the inlet temperature T₂₂.

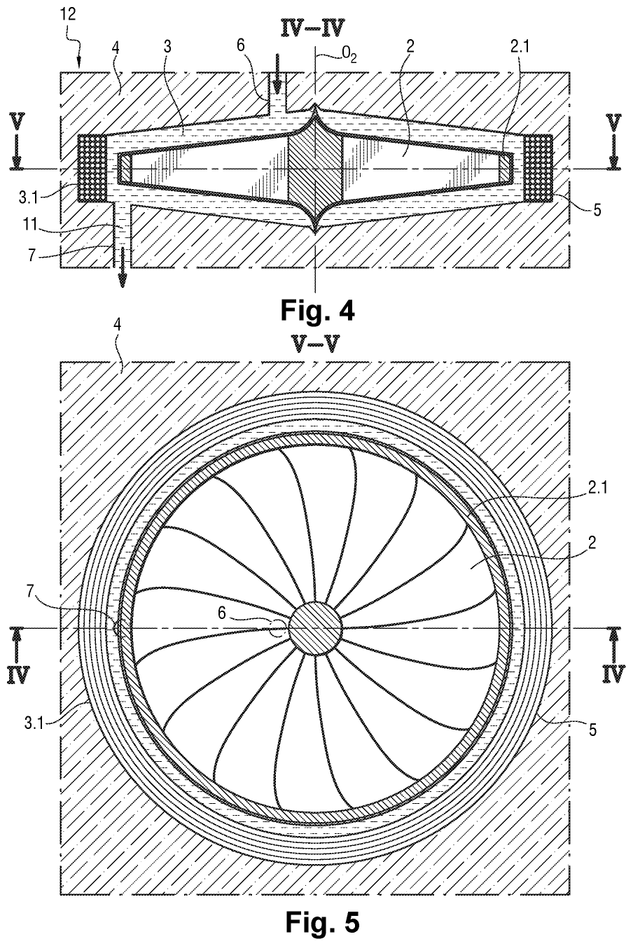

With reference to FIGS. 4 and 5, the circulation pump 12 comprises a metal turbine 2 mounted rotatably in a cylindrical housing 3 of the frame 4 of the circulation pump 12. The periphery 3.1 of the housing 3 includes stator windings 5 which remotely surround the outer edge 2.1 of the turbine 2. A glycol water 11 inlet 6 and outlet 7 provided in the frame 4 lead into the housing 3. The inlet 6 opens near the axis of rotation 0₂ of the turbine 2 and the outlet 7 opens near the outer edge 2.1 of the turbine 2. The turbine 2 is driven in rotation by means for rotating magnetic fields generated by the stator windings 5 as for a three-phase asynchronous machine. The turbine 2 is the rotor of the asynchronous machine and acts as a short-circuited armature.

In operation, the control unit 40 controls the start-up of the circulation pump 12. The first and second power supply and communication units 70 and 170 respectively keep the first and second circulators 93 and 193 and the second fans 94 and 194 off and monitor the temperature inside the first and second avionics racks 80 and 180 using the first and second temperature sensors 95 and 195. The heat generated by the first modules 81 and 82 during their operation is transmitted to the first frame 83 in the following modes:
radiation from the first modules 81 and 82 to the first frame 83 and in particular the first plate 88;
convection from the first modules 81 and 82 and the air contained in the first rack 80, then convection between the air contained in the first rack 80 and the first frame 83 and in particular the first plate 88;
conduction between the first modules 81 and 82 and the first frame 83 by the spring blades 83.1.

This heat is then transmitted by conduction to the second coil 86, which transmits it by convection to the flow of glycol water 11 circulated in the circuit 10 by the circulation pump 12. The glycol water flow 11 is cooled as it passes through the first coil 24 by a convection exchange between the first coil 24 and the air flow 33 from the exhaust air 30. The cooled glycol water 11 is then returned to the avionics rack 80. Identical heat exchanges take place between the second modules 181 and 182, the second avionics rack 180 and the closed circuit 10.

Glycol water temperature sensors 11 can be added at various points in the closed circuit 10 and connected to the control unit 40 to control the operation of the circulation pump 12 and/or the operation of the fan 32.

In case of failure of the circulation pump 12, the heating of the interior of the first avionics rack 80 is measured by the first temperature sensor 95 and detected by the first power and communication unit 70, which then controls the start-up of the first circulator 93 or even the second fan 94. The second rack 180 operates in the same way in case of failure of the circulation pump 12.

In case of failure of the cabin ventilation 31, the control unit 40 starts the first fan 32 to ensure air circulation around the first coil 24. This situation can only occur on the ground because the cabin 31 is generally ventilated by external RAM intake when the aircraft 1 is flying. The second rack 180 operates in the same way in case of failure of the ventilation system in the cabin 31.

Of course, the invention is not limited to the described embodiments but encompasses any alternative solution within the scope of the invention as defined in the claims.

More particularly:
although here the cooling device cools a first and a second avionics rack, the invention also applies to a cooling device cooling one or more avionics rack(s), which can be grouped at one point or distributed on the aircraft;
although here the avionics rack receives two electronic modules, the invention also applies to avionics racks receiving a different number of electronic modules such as a single module or more than two;
although the closed circuit here contains glycol water, the invention also applies to other types of heat-transfer fluid such as distilled water or mineral or synthetic oil;
although here the closed circuit is made of aluminium tube, the invention also applies to other types of tubes such as copper, galvanized steel or synthetic material tubes. The use of flexible hoses makes the routing of the closed circuit easier;
although here the device includes a circulation pump, the invention also applies to other types of means for circulating the heat-transfer fluid in the closed circuit, such as an in-line pump, a piston pump or a peristaltic pump;
although here the closed circuit is connected to a first and a second coil, the invention also applies to other types of heat exchangers such as plate heat exchangers, tubular heat exchangers, spiral heat exchangers or finned heat exchangers;
although here the first coil is placed opposite an air exhaust of an air-conditioned passenger cabin, the invention also applies to other types of ventilated cabins such as a cockpit, a luggage compartment, an air-conditioned or not cabin;
although here the first and second heat exchangers include a first and a second fan respectively, the invention also applies to other types of means for forcing an air flow such as a vacuum cleaner, or even to cooling devices without such means for forcing an air flow;
although here the avionics rack frame is a parallelepiped made of aluminium, the invention also applies to other types of avionics racks such as avionics racks of different shapes or other thermally conductive or non-thermally conductive materials such as copper, steel, or synthetic materials, heat exchanges with the second exchanger being possible, for example, by convection with a forced air flow in the rack rather than by conduction;
although here the modules are held in the avionics rack by bronze spring blades, the invention also applies to other means for connecting the modules to the frame, these means may be thermally conductive or not, such as metal clips or pressure pads;
although here the rack includes a resistive internal temperature sensor, the invention also applies to other means for temperature monitoring such as a thermocouple or an infrared sensor;
although here the second coil is welded to the avionics rack frame, the invention applies to other means for connecting the second coil to the avionics rack such as snap-in, bolting, gluing;
although here the first and second coils are connected to the closed circuit by flanges, the invention also applies to other types of means for connecting to the closed circuit of fluid such as welding, brazing, screwing, pressing or

1-12. (canceled)

13. A device for cooling at least one electronic module placed in an avionics rack of an aircraft comprising a ventilated cabin, the cooling device comprising:
a closed circuit for circulating a heat-transfer fluid;
first means for circulating the heat-transfer fluid in the closed circuit ;
a first heat exchanger comprising a cold circuit which is provided with first means for connecting to the closed circuit for circulating a heat-transfer fluid and which is thermally connected to a hot source of the aircraft rack;
a second heat exchanger comprising a hot circuit provided with second means for connecting to the closed circuit for circulating a heat-transfer fluid and a cold circuit thermally connected to an air exhaust of the ventilated cabin.

14. The cooling device according to claim 13, wherein the first heat exchanger comprises first means for forcing an air flow.

15. The cooling device according to claim 13, wherein the second heat exchanger comprises second means for forcing an air flow.

16. The cooling device according to claim 14, wherein the first means and/or second means for forcing an air flow comprise a fan.

17. The cooling device according to claim 13, wherein the first heat exchanger comprises second means for circulating the heat-transfer fluid in the closed circuit.

18. The cooling device according to claim 15, comprising means for controlling and supplying the first means for forcing an air flow.

19. The cooling device according to claim 13, wherein the first means for circulating the heat-transfer fluid comprise a turbine the rotor of which acts as a short-circuited armature.

20. A method for cooling an electronic module of an aircraft avionics rack comprising a first step of transferring heat from the electronic module to a closed circuit for circulating a heat-transfer fluid and a second step of removing heat from the heat-transfer fluid to an air flow extracted through an air exhaust of a ventilated cabin of the aircraft.

21. An aircraft comprising a cooling device according to claim 13.
